(19) United States
(12) Patent Application Publication
(10) Pub. No.: US 2026/0360406 A1
(43) Pub. Date: Nov. 12, 2026

(54) SEMICONDUCTOR MEMORY DEVICE INCLUDING DELAY ELEMENTS OF OUTPUT INTERFACE CIRCUIT AND OPERATING METHOD THEREOF

(71) Applicant: SAMSUNG ELECTRONICS CO., LTD., Suwon-si (KR)

(72) Inventors: Cheolmin AHN, Suwon-si (KR); Daesik MOON, Suwon-si (KR); Kihan KIM, Suwon-si (KR)

(73) Assignee: SAMSUNG ELECTRONICS CO., LTD., Suwon-si (KR)

(21) Appl. No.: 19/670,165

(22) Filed: May 7, 2026

(30) Foreign Application Priority Data
May 9, 2025 (KR) 10-2025-0060713

(51) Int. Cl. G11C 11/4076; G11C 11/4072; G11C 11/4093

(52) U.S. Cl. CPC G11C 11/4076; G11C 11/4072; G11C 11/4093

(57) ABSTRACT

A semiconductor memory device includes a memory cell array that includes a memory cell storing data, a plurality of data pins that transmit and receive the data, a plurality of output circuits that are respectively connected to the plurality of data pins, include delay circuits, respectively, and output the data through the plurality of data pins based on an internal read clock signal, and a skew compensating circuit that transmits a first control signal controlling the delay circuit of each of the plurality of output circuits to each of the plurality of output circuits.

### CROSS-REFERENCE TO RELATED APPLICATIONS

This application claims priority under 35 U.S.C. § 119 to Korean Patent Application No. 10-2025-0060713 filed on May 9, 2025, in the Korean Intellectual Property Office, the disclosures of which are incorporated by reference herein in their entireties.

### BACKGROUND

Nowadays, the performance of an electronic device to which a semiconductor memory device is applied is being improved. A data transfer rate of the semiconductor memory device is increasing.

An output interface circuit of the semiconductor memory device includes a plurality of transistors. Due to a manufacturing process, a characteristic distribution may exist between transistors on a read path of the semiconductor memory device. For example, a characteristic distribution may exist between transistors of each of output interface circuits respectively connected to a plurality of data pins.

Due to the characteristic distribution of the transistors on the read path, a skew may occur between data signals which the semiconductor memory device outputs, and the skew between the data signals may cause the reduction of performance of the semiconductor memory device. As the data transfer rate of the semiconductor memory device increases, the skew between the data signals may have a greater influence on the performance of the semiconductor memory device.

### SUMMARY

Embodiments of the present disclosure described herein relate to a semiconductor memory device including delay elements of an output interface circuit and an operating method thereof.

Embodiments of the present disclosure are directed to remove skews of a data signal DQ and a data strobe signal DQS output from a semiconductor memory device.

According to an embodiment, a semiconductor memory device may include a memory cell array that includes a memory cell storing data, a plurality of data pins that transmit and receive the data, a plurality of output circuits that are respectively connected to the plurality of data pins, include delay circuits, respectively, and output the data through the plurality of data pins based on an internal read clock signal, and a skew compensating circuit that transmits a first control signal controlling the delay circuit of each of the plurality of output circuits to each of the plurality of output circuits.

According to an embodiment, a semiconductor memory device may include a memory cell array that includes a memory cell storing data, a data pin that transmits and receives the data, an output circuit that includes a delay circuit, is connected to the data pin, and outputs an output signal obtained by carving an input signal to have a 1-UI (unit interval) pulse width based on an internal read clock signal, a sampler circuit that is connected to the data pin and the output circuit through a low pass filter, and a skew compensating circuit that transmits a control signal controlling the delay circuit to the output circuit, the low pass filter may include a resistor and a capacitor. The low pass filter may perform low pass filtering during an initialization sequence of the semiconductor memory device and operate as a resistance circuit after the initialization sequence.

According to an embodiment, an operating method of a semiconductor memory device may include determining, at the semiconductor memory device, control codes controlling delay elements respectively included in a plurality of output circuits respectively connected to a plurality of data pins, during at least one initialization sequence of the semiconductor memory device, delaying, at the semiconductor memory device, an internal read clock signal based on the control codes, after the at least initialization sequence, and outputting, at the semiconductor memory device, data through the plurality of data pins based on a delayed internal read clock signal in response to a read command of a memory controller, after the at least initialization sequence.

### BRIEF DESCRIPTION OF THE FIGURES

The above and other objects and features of the present disclosure will become apparent by describing in detail embodiments thereof with reference to the accompanying drawings.

FIG. 1 is a block diagram illustrating a memory system according to an embodiment of the present disclosure.

FIG. 2 is a diagram describing skew compensation of a memory device of FIG. 1.

FIG. 3 is a block diagram illustrating a memory device according to an embodiment of the present disclosure.

FIG. 4 is a diagram illustrating a bank array according to an embodiment of the present disclosure.

FIG. 5 is a block diagram describing a configuration associated with skew compensation of a memory device according to the embodiment of FIG. 1.

FIG. 6 is a diagram describing a low pass filter according to an embodiment of the present disclosure.

FIG. 7 is a block diagram illustrating a configuration of an output circuit according to an embodiment of the present disclosure.

FIG. 8 is a diagram describing delayed internal division clock signals and 1-UI pulses according to an embodiment of the present disclosure.

FIGS. 9A and 9B are diagrams describing a delay circuit according to an embodiment of the present disclosure.

FIGS. 10A and 10B are diagrams describing a delay circuit according to an embodiment of the present disclosure.

FIG. 11 is a diagram describing a sampler according to an embodiment of the present disclosure.

FIG. 12 is a circuit diagram of a dynamic comparator according to an embodiment of the present disclosure.

FIG. 13 is a timing diagram describing skew compensation of a memory device according to an embodiment of the present disclosure.

FIG. 14 is a flowchart describing an operating method of a memory device according to an embodiment of the present disclosure.

FIG. 15 is a flowchart describing an operating method of a skew compensating circuit according to an embodiment of the present disclosure.

### DETAILED DESCRIPTION

Below, embodiments of the present disclosure will be described in detail and clearly to such an extent that an ordinary one in the art easily carries out the present disclosure.

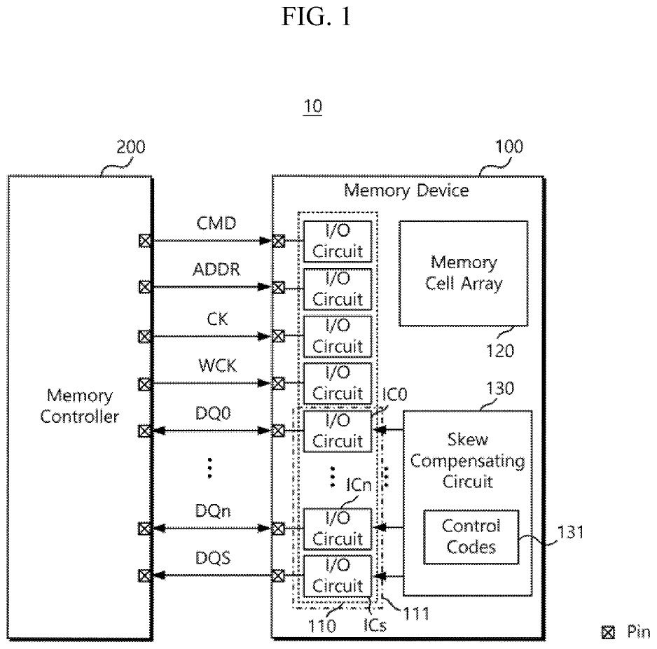

FIG. 1 is a block diagram illustrating a memory system 10 according to an embodiment of the present disclosure.

A semiconductor memory device 100 according to an embodiment of the present disclosure may output skew-free data signals DQ0, . . . DQn (collectively corresponding to DQ in the specification) shown in FIG. 1 from a plurality of data pins in response to a read command transmitted from a memory controller 200. The semiconductor memory device 100 may determine a control code for delaying an internal clock signal while performing an initialization sequence. The internal clock signal may be used to carve a data bit. The semiconductor memory device 100 may output the skew-free data signals DQ, based on the control code. In the specification, a memory device means a semiconductor memory device. The memory system 10 according to an embodiment of the present disclosure will be described in detail with reference to FIG. 1.

Referring to FIG. 1, the memory system 10 may include the memory controller 200 and the memory device 100.

The memory controller 200 may control the memory device 100. For example, the memory controller 200 may control the memory device 100 depending on a request of a processor supporting various applications such as a server application, a personal computer (PC) application, and a mobile application. For example, the memory controller 200 may be included in a host including a processor and may control the memory device 100 depending on a request of the processor.

To control the memory device 100, the memory controller 200 may transmit a command CMD and/or an address ADDR to the memory device 100. Also, the memory controller 200 may transmit the data signal DQ to the memory device 100 or may receive the data signal DQ from the memory device 100.

The memory device 100 may receive and store the data signal DQ in response to a write command from the memory controller 200. In response to the read command of the memory controller 200, the memory device 100 may read the stored data and may transmit the data signal DQ to the memory controller 200.

In an embodiment, the memory device 100 may be a memory device including volatile memory cells. For example, the memory device 100 may include various dynamic random access memory (DRAM) devices such as a double data rate synchronous DRAM (DDR SDRAM), a DDR2 SDRAM, a DDR3 SDRAM, a DDR4 SDRAM, a DDR5 SDRAM, a DDR6 SDRAM, a low power double data rate (LPDDR) SDRAM LPDDR SDRAM, an LPDDR2 SDRAM, an LPDDR3 SDRAM, an LPDDR4 SDRAM, an LPDDR4X SDRAM, an LPDDR5 SDRAM, an LPDDR6 SDRAM, a graphics double data rate synchronous graphics random access memory (GDDR SGRAM), a GDDR2 SGRAM, a GDDR3 SGRAM, a GDDR4 SGRAM, a GDDR5 SGRAM, and a GDDR6 SGRAM.

In an embodiment, the memory device 100 may be a stacked memory device, in which DRAM dies are stacked, such as a high bandwidth memory (HBM), an HBM2, or an HBM3.

In an embodiment, the memory device 100 may be a memory device which complies with the joint electron device engineering council (JEDEC) standard.

In an embodiment, the memory device 100 may be implemented with a memory module such as a dual in-line memory module (DIMM). For example, the memory module may be a registered DIMM (RDIMM), a load reduced DIMM (LRDIMM), an unbuffered DIMM (UDIMM), a fully buffered DIMM (FB-DIMM), or a small outline DIMM (SO-DIMM). Alternatively, the memory module may be an unbuffered dual in-line memory module (UDIMM), a small outline DIMM (SO-DIMM), a clocked UDIMM, or a clocked SO-DIMM (CSO-DIMM). However, this is provided as an example, and the memory module may be any other memory module such as a single in-line memory module (SIMM).

The memory device 100 may include an input/output circuit 110, a memory cell array 120, and a skew compensating circuit 130.

The input/output circuit 110 may include input circuits and output circuits 111. The input/output circuit 110 may be connected to a plurality of pins. For example, the output circuits 111 may be electrically connected to data pins and a data strobe pin.

The input/output circuit 110 may capture signals received through the pins and may convert the captured signals into internal signals or may output signals through the pins. For example, the input circuits may capture the command CMD, the address ADDR, a clock signal CK, a data clock signal WCK, and the data signal DQ received from the memory controller 200 so as to be converted into internal signals. The output circuits 111 may output the data signal DQ and the data strobe signal DQS.

The memory cell array 120 may include a plurality of banks, each of which includes memory cells for storing data. For convenience of description, in the specification, it is assumed that each bank includes DRAM cells. However, this is provided as an example, and each of the plurality of banks may be implemented to include any other volatile memory cells except for the DRAM cells. Also, the plurality of banks may be implemented to include the same kind of memory cells or may be implemented to include different kinds of memory cells.

The memory cell array 120 may include a plurality of memory cell rows. Herein, the memory cell row may refer to memory cells included in one row.

In an embodiment, the memory cell row may be defined for each bank. For example, one bank may be connected to a plurality of word lines, and memory cells connected to the same word line may constitute the same memory cell row. In this case, each bank may include a plurality of memory cell rows.

In an embodiment, the memory cell row may be defined for each sub-array block. For example, one bank may include a plurality of sub-array blocks, and memory cells, which are connected to the same word line, from among memory cells of each of the sub-array blocks may constitute the same memory cell row. In this case, each sub-array block may include a plurality of memory cell rows.

In an embodiment, the memory cell row may be defined to include memory cells of different banks. For example, two or more banks may share the same word line, and memory cells connected to the same word line and belonging to different banks may constitute the same memory cell row. However, this is provided as an example. According to an embodiment, the memory cell row may be defined in various manners.

According to an embodiment of the present disclosure, the memory device 100 may include the skew compensating circuit 130. The skew compensating circuit 130 may transmit a control signal (e.g., a control code) stored in a memory circuit 131 to each of the output circuits 111. For example, the skew compensating circuit 130 may transmit the control code including a plurality of control bits to each of the output circuits 111.

Each of the output circuits 111 may include a delay circuit. The delay circuit of each of the output circuits 111 may delay the internal clock signal, based on the control signal. For example, the delay circuit may delay an internal read clock signal based on the control signal.

Each of the output circuits 111 may carve a data bit based on the delayed internal clock signal and may generate the data signal DQ and the data strobe signal DQS.

In an embodiment, the skew compensating circuit 130 may transmit different control signals to the output circuits 111, respectively. For example, the skew compensating circuit 130 may transmit a first control signal to a first output circuit and may transmit a second control signal different from the first control signal to a second output circuit. The output circuits 111 may delay the internal clock signal as much as different delay amounts, based on different control signals.

As the output circuits 111 delay the internal clock signal as much as different delay amounts, skews of the data signal DQ and the data strobe signal DQS may be removed. Accordingly, the reliability of the memory device 100 may be improved.

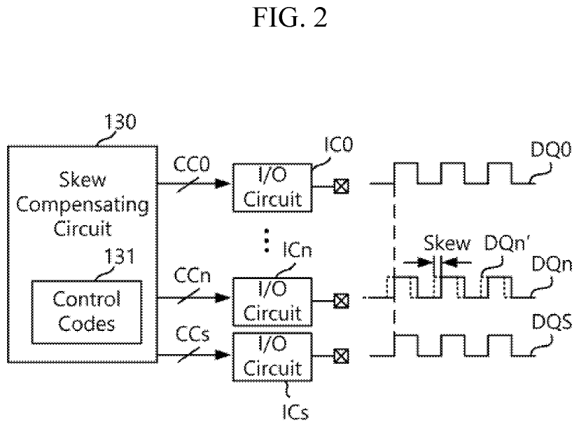

FIG. 2 is a diagram illustrating skew compensation of the memory device 100 of FIG. 1.

Referring to FIG. 2, each of output circuits IC0, . . . , ICn for outputting the data signal DQ or an output circuit ICs for outputting the data strobe signal DQS may be electrically connected to each of a plurality of pins. The output circuits IC0, . . . , ICn may output data signals DQ0, . . . , DQn, respectively, and the output circuit ICs may output the data strobe signal DQS.

The memory device 100 may determine skews of the data signals DQ0, . . . , DQn and the data strobe signal DQS output from the output circuits IC0, . . . , ICn and ICs while performing the initialization sequence. The memory device 100 may determine control signals CC0, . . . , CCn and CCs for skew compensation while performing the initialization sequence.

In an embodiment, during the tINIT3 timing prescribed by the JEDEC, the memory device 100 may determine skews of the data signals DQ0, . . . , DQn and the data strobe signal DQS output from the output circuits IC0, . . . , ICn and ICs. The memory device 100 may determine the control signals CC0, . . . , CCn and CCs for skew compensation during the tINIT3 timing prescribed by the JEDEC. In an embodiment, in addition to the tINIT3 timing, during any other timing to be performed during initialization sequences, the memory device 100 may determine a skew and may determine the control signals CC0, . . . , CCn and CCs for skew compensation.

In response to the read command, the memory device 100 may transmit the control signals CC0, . . . , CCn and CCs for skew compensation to the output circuits IC0, . . . , ICn and ICs. At least some of the output circuits IC0, . . . , ICn and ICs may be different from each other. For example, the control signal CC0 and the control signal CCn may be different control signals.

The output circuit ICn connected to a pin where a skew occurs may delay the internal clock signal based on the control signal CCn, and thus, the skew of the data signal DQn may be removed.

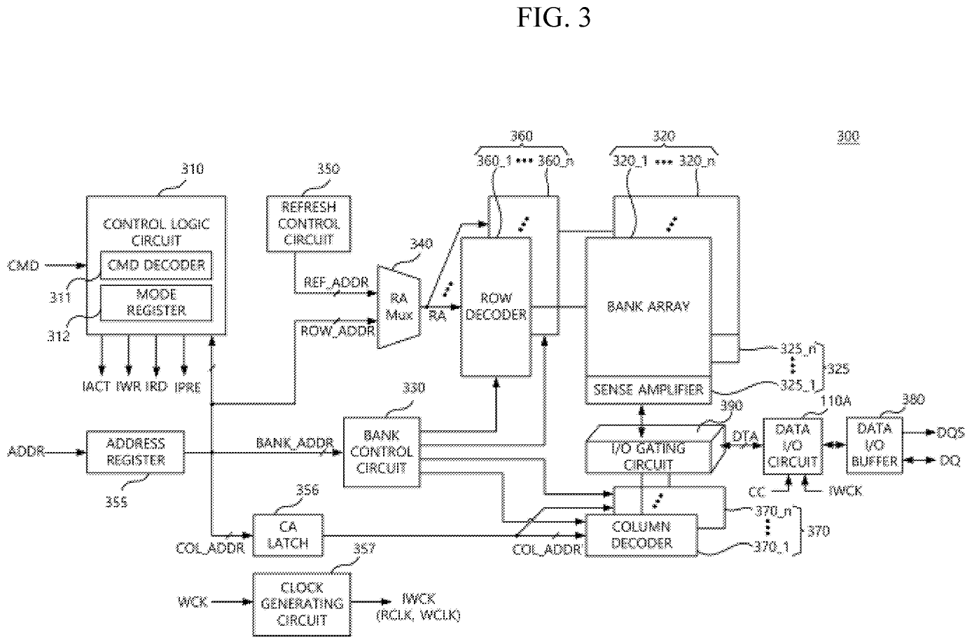

FIG. 3 is a block diagram illustrating a memory device 300 according to an embodiment of the present disclosure. The memory device 300 of FIG. 3 may correspond to the memory device 100 of FIG. 1.

Referring to FIG. 3, the memory device 300 may include a data input/output circuit 110A, a control logic circuit 310, an address register 355, bank control logic 330, a refresh control circuit 350, a row address multiplexer 340, a column address latch 356, a clock generating circuit 357, a row decoder 360, a column decoder 370, a memory cell array 320, a sense amplifier unit 325, an input/output gating circuit 390, and a data input/output buffer 380.

The memory cell array 320 may include a plurality of bank arrays 320_1 to 320_n. Each of the plurality of bank arrays 320_1 to 320_n may include a plurality of memory cells. For example, each of the plurality of memory cells may be formed at an intersection of a corresponding word line and a corresponding bit line.

The row decoder 360 may include a plurality of sub-row decoders 360_1 to 360_n. Each of the plurality of sub-row decoders 360_1 to 360_n may be connected to the corresponding bank array among the plurality of bank arrays 320_1 to 320_n.

The sense amplifier unit 325 may include a plurality of sense amplifiers 325_1 to 325_n. Each of the plurality of sense amplifiers 325_1 to 325_n may be connected to the corresponding bank array among the plurality of bank arrays 320_1 to 320_n.

The column decoder 370 may include a plurality of sub-column decoders 370_1 to 370_n. Each of the plurality of sub-column decoders 370_1 to 370_n may be connected to the corresponding bank array among the plurality of bank arrays 320_1 to 320_n through the corresponding sense amplifier.

The plurality of bank arrays 320_1 to 320_n, the plurality of sense amplifiers 325_1 to 325_n, the plurality of sub-column decoders 370_1 to 370_n, and the plurality of sub-row decoders 360_1 to 360_n may constitute a plurality of banks. For example, the first bank array 320_1, the first sense amplifier 325_1, the first sub-column decoder 370_1, and the first sub-row decoder 360_1 may constitute the first bank.

The address register 355 may receive the address ADDR including a bank address BANK_ADDR, a row address ROW_ADDR, and a column address COL_ADDR from the memory controller 200. The address register 355 may provide the received bank address BANK_ADDR to the bank control logic 330, may provide the received row address ROW_ADDR to the row address multiplexer 340, and may provide the received column address COL_ADDR to the column address latch 356.

The bank control logic 330 may generate bank control signals in response to the bank address BANK_ADDR. For example, a row decoder corresponding to the bank address BANK_ADDR from among the plurality of row decoders 360_1 to 360_n may be activated in response to the bank control signals. A column decoder corresponding to the bank address BANK_ADDR from among the plurality of column decoders 370_1 to 370_n may be activated in response to the bank control signals.

The row address multiplexer 340 may receive the row address ROW_ADDR from the address register 355 and may receive a refresh row address REF_ADDR from the refresh control circuit 350. The row address multiplexer 340 may selectively output the row address ROW_ADDR or the refresh row address REF_ADDR as a row address RA. The row address RA output from the row address multiplexer 340 may be applied to each of the plurality of row decoders 360_1 to 360_n.

In response to refresh signals from the control logic circuit 310, the refresh control circuit 350 may sequentially increase or decrease the refresh row address REF_ADDR in a normal refresh mode.

A sub-row decoder selected by the bank control logic 330 from among the plurality of sub-row decoders 360_1 to 360_n may activate a word line corresponding to the row address RA output from the row address multiplexer 340. For example, the selected sub-row decoder may apply a word line driving voltage to the word line corresponding to the row address RA.

The column address latch 356 may receive the column address COL_ADDR from the address register 355 and may temporarily store the received column address COL_ADDR. Also, for example, in a burst mode, the column address latch 356 may sequentially increase the received column address COL_ADDR. The column address latch 356 may apply the temporarily stored or sequentially increased column address COL_ADDR′ to each of the plurality of column decoders 370_1 to 370_n.

A sub-column decoder activated by the bank control logic 330 from among the plurality of sub-column decoders 370_1 to 370_n may activate a sense amplifier corresponding to the bank address BANK_ADDR and the column address COL_ADDR through the input/output gating circuit 390.

The input/output gating circuit 390 may include circuits which gate input/output data. Also, the input/output gating circuit 390 may include data latches for storing a codeword output from the plurality of bank arrays 320_1 to 320_n and write drivers for writing data in the plurality of bank arrays 320_1 to 320_n.

In an embodiment, in the read operation, data DTA read from a selected bank array among the plurality of bank arrays 320_1 to 320_n may be sensed by a sense amplifier corresponding to the selected bank array and may be stored in the data latches of the input/output gating circuit 390. Also, the data DTA stored in the data latches may be provided to the data input/output buffer 380.

In an embodiment, in the write operation, as the data DTA to be written in a selected bank array among the plurality of bank arrays 320_1 to 320_n may be received by the data input/output buffer 380 as the data signal DQ. The input/output gating circuit 390 may write the data DTA in the selected bank array.

The control logic circuit 310 may control the operation of the memory device 300. For example, the control logic circuit 310 may generate control signals such that the memory device 300 performs the write operation, the read operation, and the refresh operation. The control logic circuit 310 may include a command decoder 311 which decodes the command CMD received from the memory controller 200 and a mode register (MRS) 312 for setting an operation mode of the memory device 300.

The command decoder 311 may decode the command CMD and may generate internal command signals such as an internal active signal IACT, an internal precharge signal IPRE, an internal read signal IRD, and an internal write signal IWR. Also, the command decoder 311 may generate control signals corresponding to the command CMD by decoding a chip select signal, a command/address signal, etc.

The clock generating circuit 357 may receive the data clock signal WCK. The clock generating circuit 357 may output an internal clock signal IWCK to the data input/output circuit 110A based on the data clock signal WCK. For example, the clock generating circuit 357 may output the internal read clock signal and an internal write clock signal to the data input/output circuit 110A. The internal clock signal IWCK may be used for the read operation and the write operation in the data input/output circuit 110A.

In an embodiment, the clock generating circuit 357 may output internal division clock signals. For example, the clock generating circuit 357 may output internal read division clock signals having different phases as the internal read clock signal and may output internal write division clock signals having different phases as the internal write clock signal.

The data input/output circuit 110A according to an embodiment of the present disclosure may generate the data signal DQ based on the control signal CC, the internal clock signal IWCK, and the data DTA and may provide the data signal DQ to the memory controller 200 through the data input/output buffer 380 and a pin together with the data strobe signal DQS.

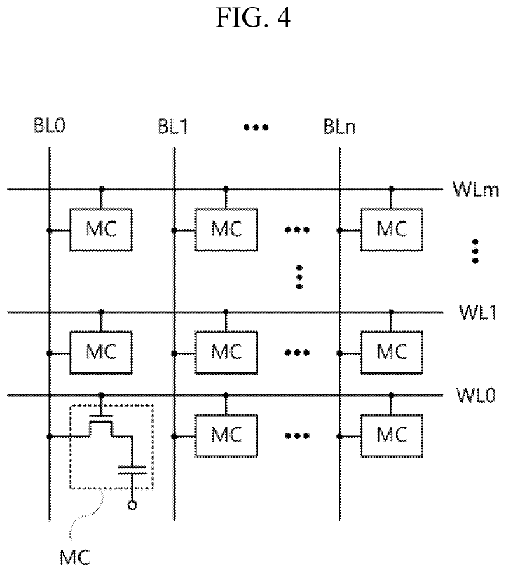

FIG. 4 is a diagram illustrating a bank array according to an embodiment of the present disclosure.

FIG. 4 is a diagram illustrating an example of a bank array according to an embodiment of the present disclosure. The bank array of FIG. 4 may correspond, for example, to the first bank array 320_1 of FIG. 3.

Referring to FIGS. 3 and 4, the first bank array 320_1 may include a plurality of word lines WL0 to WLm, a plurality of bit lines BL0 to BLn, and a plurality of memory cells MC disposed at intersections of the word lines WL0 to WLm and the bit lines BL0 to BLn.

In an embodiment, each of the memory cells MC may be a DRAM cell. For example, each memory cell MC may include a cell transistor connected to a word line and a bit line and a cell capacitor connected to the cell transistor.

In the specification, a word line extending in a row direction may be referred to as a “row” of the first bank array 320_1. In the specification, a bit line extending in a columns direction may be referred to as a “column” of the first bank array 320_1.

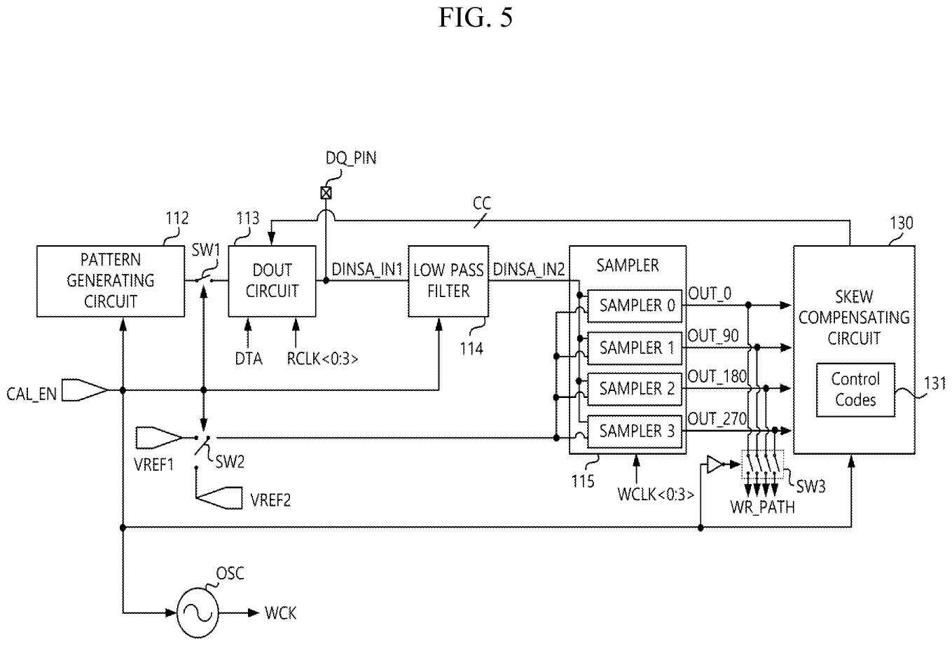

FIG. 5 is a block diagram describing a configuration associated with skew compensation of the memory device 100 according to the embodiment of FIG. 1.

Referring to FIG. 5, the memory device 100 may include a pattern generating circuit 112, an output circuit 113, a low pass filter 114, a sampler 115, and the skew compensating circuit 130.

When the read command is received, the output circuit 113 may independently carve data bits of the data DTA based on an internal read clock signal RCLK<0:3> and may generate the data signal DQ. The data signal DQ may be output through a data pin DQ_PIN. As in the above data signal DQ, the output circuit 113 may generate the data strobe signal DQS based on the internal read clock signal RCLK<0:3> and may output the data strobe signal DQS through a data strobe pin. The internal read clock signal RCLK<0:3> may include internal read division clock signals RCLK<0>, RCLK<1>, RCLK<2>, and RCLK<3>.

When the read command is received, the output circuit 113 according to an embodiment of the present disclosure may delay the internal read clock signal RCLK<0:3> based on the control signal CC received from the skew compensating circuit 130 and may generate the data signal DQ and the data strobe signal DQS based on the delayed internal read clock signal.

In an embodiment, the control signal CC may include different control codes respectively corresponding to the internal read division clock signals RCLK<0>, RCLK<1>, RCLK<2>, and RCLK<3>.

For example, the output circuit 113 may delay the first internal read division clock signal RCLK<0> based on a first control code, may delay the second internal read division clock signal RCLK<1> based on a second control code, may delay the third internal read division clock signal RCLK<2> based on a third control code, and may delay the fourth internal read division clock signal RCLK<3> based on a fourth control code.

The skew compensating circuit 130 may transmit the control signal CC to the output circuit 113 in response to a deactivated calibration enable signal CAL_EN. As will be described below, the skew compensating circuit 130 may determine the control signal CC in response to the calibration enable signal CAL_EN.

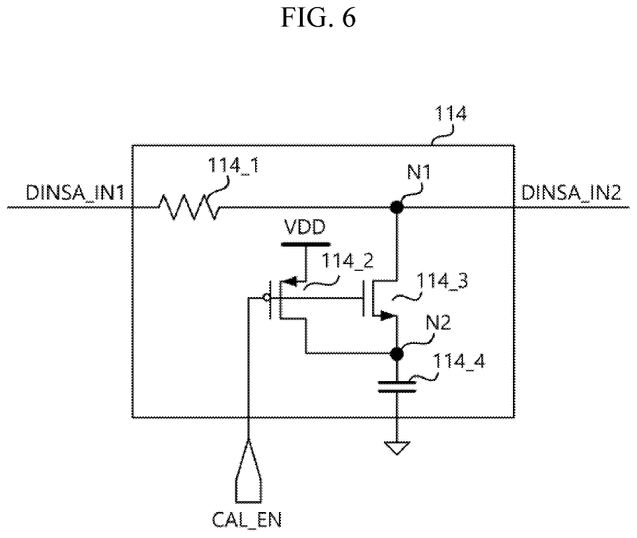

The data signal DQ received through the data pin DQ_PIN may be input to the sampler 115 through the low pass filter 114. As will be described with reference to FIG. 6, the low pass filter 114 may operate as a simple resistance circuit after the initialization sequence. Accordingly, the low pass filter 114 may not perform low pass filtering on an input signal DINSA_IN1 after the initialization sequence.

When the write command is received, the sampler 115 may sample an input signal DINSA_IN2 based on a second reference voltage VREF2 and an internal write clock signal WCLK<0:3>. For example, the sampler 115 may sample the input signal DINSA_IN2 in synchronization with each of internal write division clock signals WCLK<0>, WCLK<1>, WCLK<2>, and WCLK<3> and may provide sampled signals OUT_0, OUT_90, OUT_180, and OUT_270 to a write path WR_PATH. A third switch SW3 which connects the sampler 115 and the write path WR_PATH may be turned on by the deactivated calibration enable signal CAL_EN.

In the specification, the description will be given under the assumption that the internal read division clock signals RCLK<0>, RCLK<1>, RCLK<2>, and RCLK<3> are four signals with different phases and the internal write division clock signals WCLK<0>, WCLK<1>, WCLK<2>, and WCLK<3> are four signals with different phases, but embodiments of the present disclosure are not limited thereto. For example, internal read division clock signals may be implemented with signals of different phases, the number of which is less than 4 or exceeds 4; internal write division clock signals may be implemented with signals of different phases, the number of which is less than 4 or exceeds 4.

The memory device 100 of the present disclosure may generate the calibration enable signal CAL_EN during the initialization sequence. The calibration enable signal CAL_EN may be provided to the pattern generating circuit 112, the low pass filter 114, and the skew compensating circuit 130. The calibration enable signal CAL_EN may be provided to a first switch SW1, a second switch SW2, and the third switch SW3.

The memory device 100 may include an oscillator OSC which internally generates the data clock signal WCK in response to the calibration enable signal CAL_EN during the initialization sequence. The data clock signal WCK generated by the oscillator OSC during the initialization sequence may be input to the clock generating circuit 357 of FIG. 3, and the clock generating circuit 357 may provide the internal clock signals RCLK and WCLK to the output circuit 113 and the sampler 115.

The pattern generating circuit 112 may generate a pattern signal, which maintains the high level, in response to the calibration enable signal CAL_EN.

The first switch SW1 may be turned on in response to the calibration enable signal CAL_EN and may provide the pattern signal to the output circuit 113.

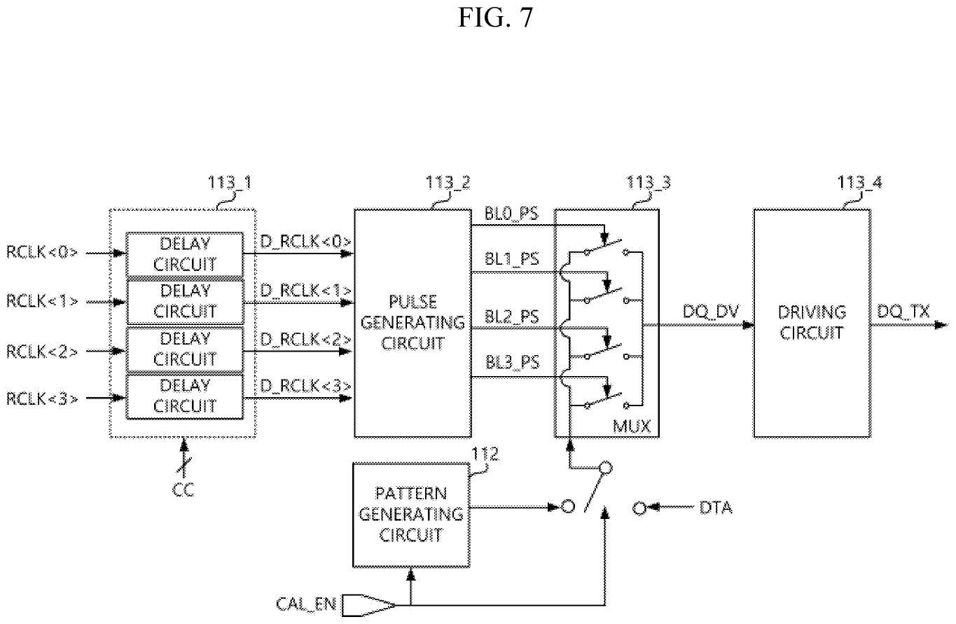

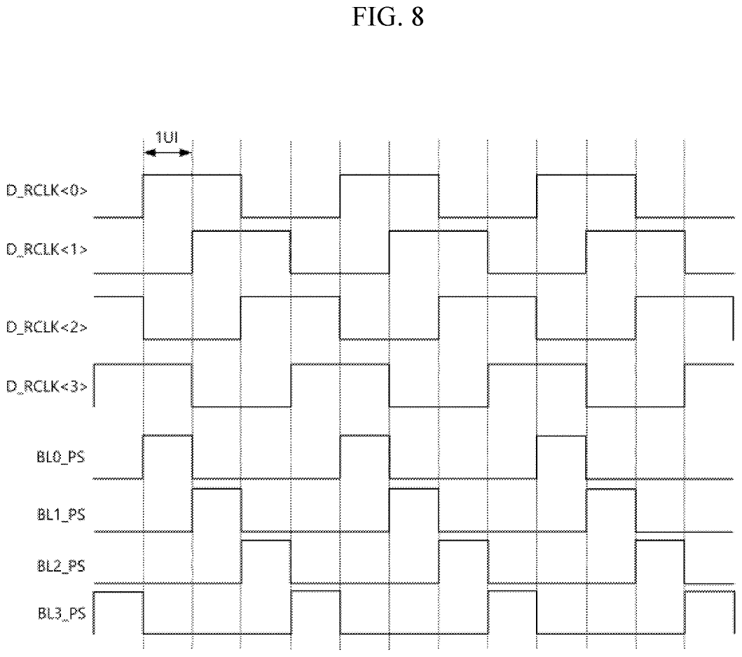

The output circuit 113 may carve the pattern signal based on the internal read clock signal RCLK<0:3>, so as to have a 1-UI (unit interval) pulse width. For example, the output circuit 113 may carve the pattern signal based on each of the internal read division clock signals RCLK<0>, RCLK<1>, RCLK<2>, and RCLK<3>, so as to have the 1-UI pulse width. How to carve the pattern signal will be described in detail with respect to FIGS. 7 and 8.

The carved pattern signal DINSA_IN1 may be input to the low pass filter 114. The low pass filter 114 may output a direct current (DC) signal DINSA_IN2, which is obtained by performing low filtering on the carved pattern signal DINSA_IN1, in response to the calibration enable signal CAL_EN. The DC signal DINSA_IN2 may be input to each of a plurality of sampler circuits of the sampler 115.

The plurality of sampler circuits may respectively output results OUT_0, OUT_90, OUT_180, OUT_270, which are obtained by comparing a first reference voltage VREF1 and the DC signal DINSA_IN2, to the skew compensating circuit 130, based on the first reference voltage VREF1 and the internal write clock signal WCLK<0:3>. The first reference voltage VREF1 may be input to each of the plurality of sampler circuits through the second switch SW2 turned on in response to the calibration enable signal CAL_EN.

The skew compensating circuit 130 may determine the control signal CC based on the comparison results OUT_0, OUT_90, OUT_180, and OUT_270 in response to the calibration enable signal CAL_EN. The control signal CC may be stored in the memory circuit 131 as a control code including a plurality of control bits. For example, the skew compensating circuit 130 may store the control code in a register.

In an embodiment, the skew compensating circuit 130 may determine control signals respectively corresponding to the internal read division clock signals RCLK<0>, RCLK<1>, RCLK<2>, and RCLK<3>.

For example, the skew compensating circuit 130 may store a first control code, a second control code, a third control code, and a fourth control code respectively corresponding to the first internal read division clock signal RCLK<0>, the second internal read division clock signal RCLK<1>, the third internal read division clock signal RCLK<2>, and the fourth internal read division clock signal RCLK<3> in the memory circuit 131.

In an embodiment, low pass filtering may be performed on the pattern signal DINSA_IN1 carved to have the 1-UI pulse width, based on the first internal read division clock signal RCLK<0>. The skew compensating circuit 130 may determine the first control code, based on a result of comparing the DC signal DINSA_IN2 experiencing low pass filtering and the first reference voltage VREF1. As in the above description, the skew compensating circuit 130 may determine the second control code, the third control code, and the fourth control code.

FIG. 6 is a diagram describing the low pass filter 114 according to an embodiment of the present disclosure. The low pass filter 114 of FIG. 6 may correspond to the low pass filter 114 of FIG. 5.

Referring to FIG. 6, the low pass filter 114 may include a resistor 114_1, a first node N1, a first switch transistor 114_3, a capacitor 114_4, a second switch transistor 114_2, and a second node N2.

The resistor 114_1 may receive the input signal DINSA_IN1 and may output the input signal DINSA_IN1 to the first node N1. The input signal DINSA_IN1 may be the data signal DQ received from the data pin when the read command is received or may be a signal received from the output circuit 113 of FIG. 5 during the initialization sequence.

The first switch transistor 114_3 may connect the first node N1 and the capacitor 114_4. The second switch transistor 114_2 may connect a supply voltage electrode VDD and the capacitor 114_4.

The first switch transistor 114_3 is turned off by the deactivated calibration enable signal CAL_EN; in this case, the capacitor 114_4 is electrically separated from the first node N1. Accordingly, the low pass filter 114 may operate as a resistance circuit, and the data signal DQ received from the data pin may be transmitted to the sampler 115 of FIG. 5 as the output signal DINSA_IN2 through the resistor 114_1 and the first node N1.

The second switch transistor 114_2 may be turned on by the deactivated calibration enable signal CAL_EN; in this case, the capacitor 114_4 may perform decoupling between the supply voltage electrode VDD and a ground voltage through the second node N2.

The first switch transistor 114_3 is turned on by the activated calibration enable signal CAL_EN; in this case, the capacitor 114_4 is electrically connected to the first node N1. Accordingly, the low pass filter 114 may perform low pass filtering on the input signal DINSA_IN1. A result of performing low pass filtering on the input signal DINSA_IN1 received from the output circuit 113 of FIG. 5, that is, the DC signal DINSA_IN2 may be transmitted to the sampler 115 of FIG. 5.

FIG. 7 is a block diagram illustrating a configuration of an output circuit according to an embodiment of the present disclosure. An output circuit of FIG. 7 may correspond to the output circuit 113 of FIG. 5. The output circuit 113 will be described with reference to FIGS. 5 and 7.

The output circuit 113 according to an embodiment of the present disclosure may include a plurality of delay circuits 113_1, a pulse generating circuit 113_2, a multiplexer 113_3, and a driving circuit 113_4.

The plurality of delay circuits 113_1 may respectively receive the internal read division clock signals RCLK<0>, RCLK<1>, RCLK<2>, and RCLK<3> and may respectively delay the internal read division clock signals RCLK<0>, RCLK<1>, RCLK<2>, and RCLK<3> based on the control signal CC. The plurality of delay circuits 113_1 may output delayed internal read division clock signals D_RCLK<0>, D_RCLK<1>, D_RCLK<2>, and D_RCLK<3>, respectively.

In an embodiment, based on different control codes, the plurality of delay circuits 113_1 may delay the internal read division clock signals RCLK<0>, RCLK<1>, RCLK<2>, and RCLK<3> as much as different delay amounts, respectively. The control signal CC may include control codes respectively corresponding to the plurality of delay circuits 113_1. The control code may include a plurality of control bits.

The pulse generating circuit 113_2 may output a plurality of 1-UI pulses BL0_PS, BL1_PS, BL2_PS, and BL3_PS whose high levels do not overlap each other, based on the delayed internal read division clock signals D_RCLK<0>, D_RCLK<1>, D_RCLK<2>, and D_RCLK<3>.

Referring to FIG. 8, the delayed internal read division clock signals D_RCLK<0>, D_RCLK<1>, D_RCLK<2>, and D_RCLK<3> may have a phase difference of 90 degrees. For example, the clock generating circuit 357 of FIG. 3 may respectively generate the internal read division clock signals RCLK<0>, RCLK<1>, RCLK<2>, and RCLK<3> from the data clock signal WCK through phase shift. The phase difference between the delayed internal read division clock signals D_RCLK<0>, D_RCLK<1>, D_RCLK<2>, and D_RCLK<3> may be the same as the phase difference between the internal read division clock signals RCLK<0>, RCLK<1>, RCLK<2>, and RCLK<3>.

FIG. 8 is a diagram describing delayed internal division clock signals and 1-UI pulses according to an embodiment of the present disclosure.

Referring to FIG. 8, because the delayed internal read division clock signals D_RCLK<0>, D_RCLK<1>, D_RCLK<2>, and D_RCLK<3> have the same duty, high-level periods of the delayed internal read division clock signals D_RCLK<0>, D_RCLK<1>, D_RCLK<2>, and D_RCLK<3> overlap each other in some time periods. The pulse generating circuit 113_2 of FIG. 7 prevents two adjacent internal read division clock signals, whose phases are adjacent to each other, from among the delayed internal read division clock signals D_RCLK<0>, D_RCLK<1>, D_RCLK<2>, and D_RCLK<3> from having the high level at the same time. Accordingly, each of the 1-UI pulses BL0_PS, BL1_PS, BL2_PS, and BL3_PS rises at a rising edge of a corresponding one among the delayed internal read division clock signals D_RCLK<0>, D_RCLK<1>, D_RCLK<2>, and D_RCLK<3> and falls at a rising edge of a subsequent delayed internal read division clock signal. As a result, the pulse generating circuit 113_2 may generate the 1-UI pulses BL0_PS, BL1_PS, BL2_PS, and BL3_PS having waveforms whose high levels do not overlap each other (or having waveforms from which periods where high levels of signals overlap each other are removed), as illustrated in FIG. 8. For example, the first 1-UI pulse BL0_PS may be generated as an output of an AND gate receiving the first internal read division clock signal D_RCLK<0> and an inverse signal of the second internal read division clock signal D_RCLK<1>. As in the above first 1-UI pulse BL0_PS, the second 1-UI pulse BL1_PS, the third 1-UI pulse BL2_PS, and the fourth 1-UI pulse BL3_PS may be generated.

Returning to FIG. 7, the multiplexer 113_3 may carve input signals based on the 1-UI pulses BL0_PS, BL1_PS, BL2_PS, and BL3_PS, respectively, so as to have the 1-UI pulse width. For example, the multiplexer 113_3 may carve the pattern signal, which the pattern generating circuit 112 outputs during the initialization sequence, so as to have the 1-UI pulse width. The pattern signal may be a DC signal which continuously maintains the high level. After the initialization sequence, the multiplexer 113_3 may carve the data DTA so as to have the 1-UI pulse width. For example, the multiplexer 113_3 may carve each data bit so as to have the 1-UI pulse width.

The multiplexer 113_3 may output a driving signal DQ_DV, in which each input signal is carved to have the 1-UI pulse width, to the driving circuit 113_4. The multiplexer 113_3 may output a serialized driving signal DQ_DV. For example, an input signal carved by the first 1-UI pulse BL0_PS, an input signal carved by the second 1-UI pulse BL1_PS, an input signal carved by the third 1-UI pulse BL2_PS, and an input signal carved by the fourth 1-UI pulse BL3_PS may be sequentially output.

The driving circuit 113_4 may output a transmission signal DQ_TX based on the driving signal DQ_DV. A configuration of the driving circuit 113_4 may be the same as or similar to a driving circuit of a general memory device.

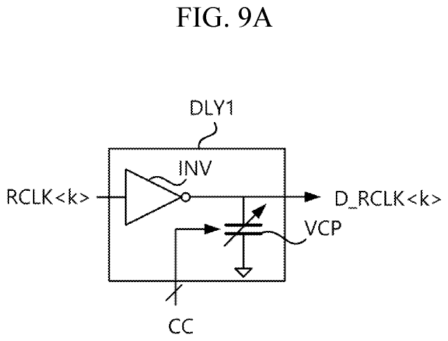

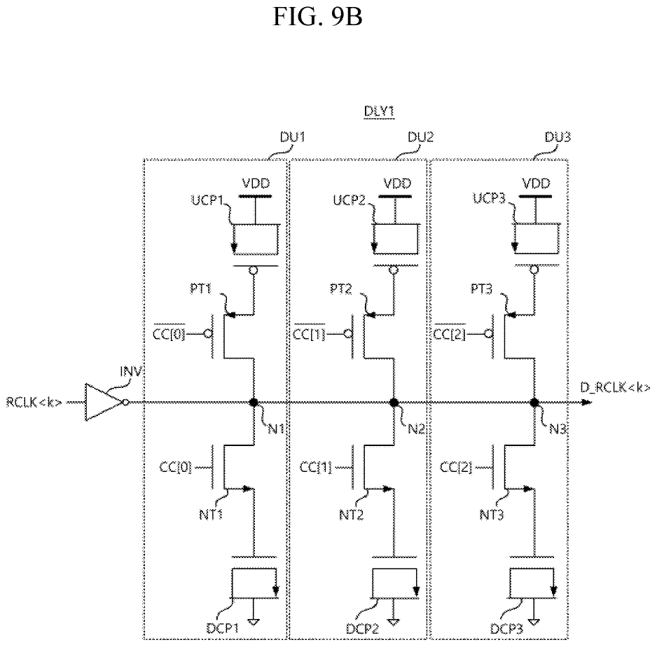

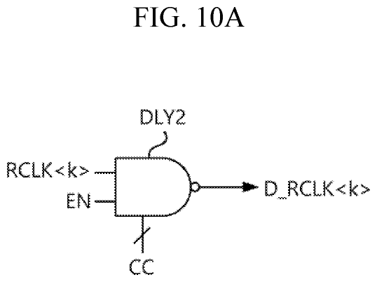

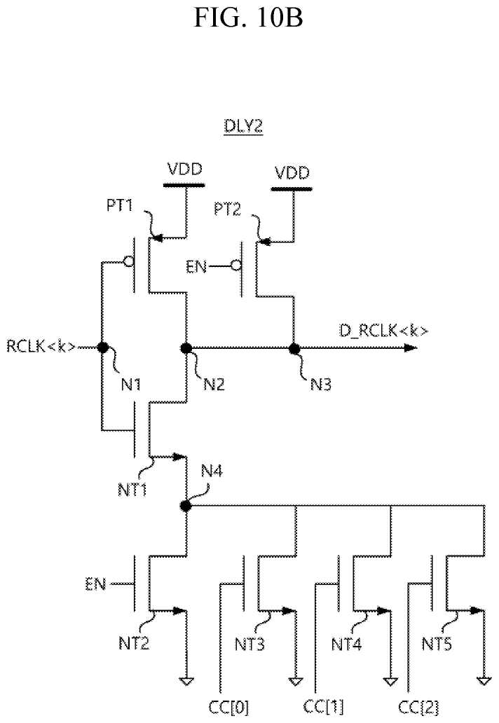

FIGS. 9A, 9B, 10A, and 10B are diagrams describing delay circuits DLY1 and DLY2 according to an embodiment of the present disclosure. The delay circuits DLY1 and DLY2 of FIGS. 9A, 9B, 10A, and 10B may correspond to one of the delay circuits 113_1 of FIG. 7.

Referring to FIGS. 9A and 10A, each of the delay circuits DLY1 and DLY2 may be provided with the internal read division clock signal RCLK<k> (k being an integer of 0 or more) and an enable signal and may delay the internal read division clock signal RCLK<k> based on the control signal CC. Each of the delay circuits DLY1 and DLY2 may output a delayed internal read division clock signal D_RCLK<k>. The delay circuits DLY1 and DLY2 may delay the internal read division clock signal RCLK<k> as much as different delay amounts, based on the control signal CC.

Referring to FIG. 9A, the delay circuit DLY1 may include an inverter element INV and a variable capacitor VCP coupled to an output path of the inverter element INV. The capacitance of the variable capacitor VCP may be controlled by the control signal CC. A slew rate of the delayed internal read division clock signal D_RCLK<k> being an output signal of the inverter element INV may be changed by the capacitance of the variable capacitor VCP. As a result, at least one of the 1-UI pulses BL0_PS, BL1_PS, BL2_PS, and BL3_PS of FIG. 8, which is generated based on the delayed internal read division clock signal D_RCLK<k>, may be shifted, and the skews of the 1-UI pulses BL0_PS, BL1_PS, BL2_PS, and BL3_PS may be compensated for.

FIG. 9B illustrates a circuit diagram according to an embodiment of the delay circuit DLY1 of FIG. 9A. Referring to FIG. 9B, unit delay circuits DU1, DU2, and DU3 having the same structure may be respectively coupled to nodes N1, N2, and N3 on a path of the output signal of the inverter element INV. The unit delay circuits DU1, DU2, and DU3 may include p-type metal-oxide-semiconductor field-effect transistors (pMOSFETs) PT1, PT2, and PT3 respectively connected to the nodes N1, N2, and N3 and metal-oxide-semiconductor (MOS) capacitors UCP1, UCP2, and UCP3 respectively connected to the pMOSFETs PT1, PT2, and PT3. The unit delay circuits DU1, DU2, and DU3 may further include nMOSFETs NT1, NT2, and NT3 respectively connected to the nodes N1, N2, and N3 and MOS capacitors DCP1, DCP2, and DCP3 respectively connected to the nMOSFETs NT1, NT2, and NT3.

The nMOSFETs NT1, NT2, and NT3 may receive control bits CC[0], CC[1], and CC[2] of a control signal through gate terminals thereof, respectively, and the pMOSFETs PT1, PT2, and PT3 may receive inverse signals C̅C̅[̅0̅]̅, C̅C̅[̅1̅]̅, and C̅C̅[̅2̅]̅ of the control bits of the control signals through gate terminals thereof, respectively. The nMOSFETs NT1, NT2, and NT3 and the pMOSFET PT1, PT2, and PT3 may be turned on or turned off by the control signal, and the MOS capacitors UCP1, UCP2, UCP3, DCP1, DCP2, and DCP3 may provide a capacitance to the output path of the delayed internal read division clock signal D_RCLK<k>. As a result, the slew rate of the delayed internal read division clock signal D_RCLK<k> may change.

Referring to FIG. 10A, the delay circuit DLY2 may include a NAND gate. The NAND gate may receive an internal read division clock signal RCLK<k> through one input terminal and an enable signal EN through another input terminal. The delayed internal read division clock signal D_RCLK<k> may be output through an output terminal in response to a control signal CC received through a control terminal. A slew rate of the delayed internal read division clock signal D_RCLK<k> being an output signal of the NAND gate may be changed based on the control signal CC.

FIG. 10B illustrates a circuit diagram according to an embodiment of the delay circuit DLY2 of FIG. 10A. Referring to FIG. 10B, the internal read division clock signal RCLK<k> is input through a first node N1 which is connected in common to gate terminal of a first pMOSFET PT1 and a first nMOSFET NT1 connected in series. The delayed internal read division clock signal D_RCLK<k> is output through a second node N2 which is a common drain node of the first pMOSFET PT1 and the first nMOSFET NT1. A second pMOSFET PT2 which connects a third node N3 and a supply voltage electrode VDD is connected to the output path of the delayed internal read division clock signal D_RCLK<k>. The second pMOSFET PT2 receives an enable signal EN through a gate terminal thereof. A plurality of nMOSFETs NT2, NT3, NT4, and NT5 is connected in parallel to a fourth node N4 which is a source node of the first nMOSFET NT1. In an embodiment, the nMOSFETs NT3, NT4, and NT5 may have different sizes. The second nMOSFET NT2 receives the enable signal EN through a gate terminal thereof, and the remaining nMOSFETs NT3, NT4, and NT5 receive the control bits CC[0], CC[1], and CC[2] of the control signal through gate terminals thereof, respectively. The slew rate of the delayed internal read division clock signal D_RCLK<k> may be changed by the nMOSFETs NT3, NT4, and NT5. The slew rate of the delayed internal read division clock signal D_RCLK<k> may be determined differently depending on the number of transistors turned on from among the nMOSFETs NT3, NT4, and NT5. Accordingly, the slew rate of the delayed internal read division clock signal D_RCLK<k> may change based on the control signal, and at least one of the 1-UI pulses BL0_PS, BL1_PS, BL2_PS, and BL3_PS of FIG. 8 may be shifted.

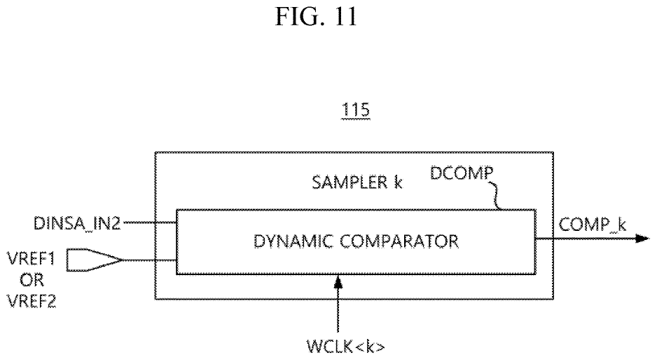

FIG. 11 is a diagram describing a sampler according to an embodiment of the present disclosure. The sampler 115 of FIG. 11 may correspond to the sampler 115 of FIG. 5.

Referring to FIG. 11, the sampler 115 may include a dynamic comparator DCOMP.

The sampler 115 may receive the input signal DINSA_IN2 and the reference voltage VREF1 or VREF2. As described with reference to FIG. 5, the sampler 115 may receive the first reference voltage VREF1 during the initialization sequence and may receive the second reference voltage VREF2 after the initialization sequence.

The sampler 115 may compare the input signal DINSA_IN2 and the reference voltage VREF1 or VREF2, based on an internal write division clock signal WCLK<k>. The sampler 115 may compare and sample the input signal DINSA_IN2 being the data signal DQ received through the data pin after the initialization sequence with the second reference voltage VREF2. A sampled data signal COMP_k may be stored in a memory cell in response to the write command. The sampler 115 may output a result COMP_k of comparing the input signal DINSA_IN2 being a DC signal received an output circuit through a low pass filter during the initialization sequence with the first reference voltage VREF1. The skew compensating circuit 130 of FIG. 5 may determine the control code based on the comparison result COMP_k obtained based on the first reference voltage VREF1.

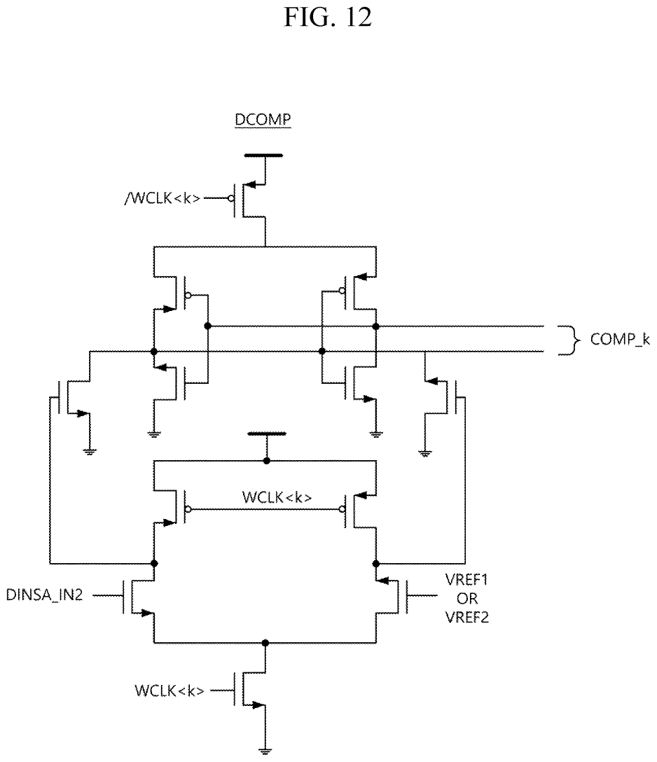

FIG. 12 is a circuit diagram of the dynamic comparator DCOMP according to an embodiment of the present disclosure. The dynamic comparator DCOMP of FIG. 12 may correspond to the dynamic comparator DCOMP of the sampler 115 of FIG. 11. Alternatively, the sampler 115 of FIG. 11 may use a comparator different from the dynamic comparator DCOMP of FIG. 12.

FIG. 12 illustrates a circuit diagram of a double tail latched comparator. The dynamic comparator DCOMP of FIG. 12 is a double tail latched comparator well known, and thus, additional description will be omitted to avoid redundancy.

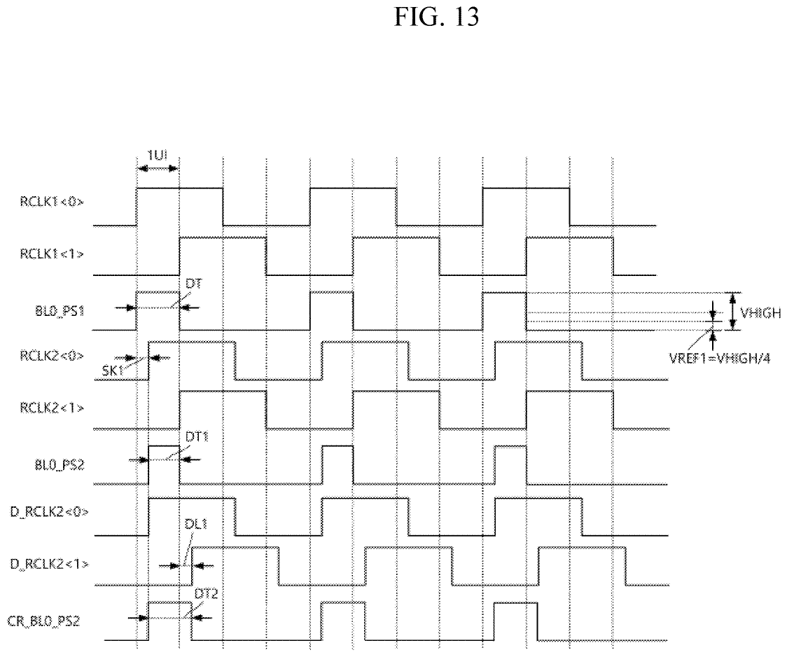

FIG. 13 is a timing diagram describing skew compensation of the memory device 100 of FIG. 1 according to an embodiment of the present disclosure.

FIG. 13 illustrates a first 1-UI pulse BL0_PS1 which has a normal 1-UI pulse width DT based on the first and second internal read division clock signals RCLK1<0> and RCLK1<1>.

FIG. 13 illustrates a first 1-UI pulse BL0_PS2 having a pulse width DT1 smaller than the normal 1-UI pulse width DT based on a first internal read division clock signal RCLK2<0> where a skew SK1 occurs and a second internal read division clock signal RCLK2<1>.

FIG. 13 illustrates a compensated first 1-UI pulse CR_BL0_PS2 which has the same pulse width DT2 as the normal 1-UI pulse width DT based on a delayed first internal read division clock signal D_RCLK2<0> and a delayed second internal read division clock signal D_RCLK2<1>.

The skew compensating circuit 130 of FIG. 5 may determine a delay amount DL1 of the second internal read division clock signal RCLK2<1>, based on a result of comparing the magnitude of the DC signal, which is obtained by performing low pass filtering on the first 1-UI pulse BL0_PS2 having the small pulse width DT1 during the initialization sequence, with the first reference voltage VREF1 and may determine the control signal based on the delay amount DL1. After the initialization sequence, the skew compensating circuit 130 may transmit the control signal determined based on the delay amount DL1 to the output circuit 113 of FIG. 5. The output circuit 113 may carve the data signal DQ based on the compensated first 1-UI pulse CR_BL0_PS2, and thus, the skew of the data signal DQ may be removed.

Continuing to refer to FIG. 13, a ratio of an on duty and an off duty of the first 1-UI pulse BL0_PS 1 is 1:3. Accordingly, the magnitude of the DC signal which is obtained by performing low pass filtering on the first 1-UI pulse BL0_PS1 generated based on the normal first and second internal read division clock signals RCLK 1<0> and RCLK 1<1> corresponds to ¼ of the high level VHIGH of the on duty of the first 1-UI pulse BL0_PS1. Accordingly, the first reference voltage VREF1 may be in advance set to ¼ of the magnitude of the high level VHIGH of the on duty of the normal first 1-UI pulse BL0_PS1, and the skew compensating circuit 130 of FIG. 5 may determine the control signal for delaying an internal read division clock signal based on a result of comparing the magnitude of the DC signal obtained by performing low pass filtering on the 1-UI pulse with the first reference voltage VREF1 during the initialization sequence.

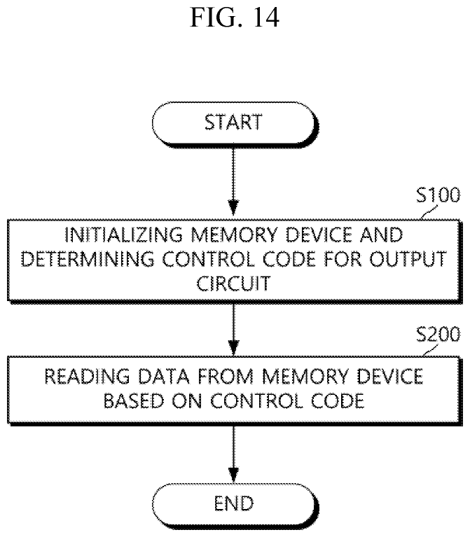

FIG. 14 is a flowchart describing an operating method of the memory device 100 of FIG. 1 according to an embodiment of the present disclosure. The operating method of the memory device 100 will be described with reference to FIGS. 2, 5, and 14.

Referring to FIG. 14, in operation S100, the memory device 100 may perform initialization sequence of the memory device 100. The initialization sequence may include an initialization sequence prescribed in the JEDEC and other initialization sequences.

During the execution of the initialization sequence, the memory device 100 may determine a control code controlling delay elements of the output circuit 113. The output circuit 113 may include a plurality of output circuits. For example, the output circuits may be respectively connected to a plurality of data pins and a data strobe pin, as described with reference to FIGS. 2, 5, and 7. Each of the output circuits 113 may include a plurality of delay elements.

During the initialization sequence, the skew compensating circuit 130 of FIG. 5 may compare the DC signal input to the sampler 115 from the output circuit 113 through the low pass filter with the first reference voltage VREF1 and may determine the control code. The control code may be determined for each of the delay circuits 113_1 respectively receiving the plurality of internal read division clock signals RCLK<0>, RCLK<1>, RCLK<2>, and RCLK<3>.

In operation S200, the memory device 100 may read data from a memory cell array in response to a read command of a memory controller and may output a data signal through a data pin based on the read data. The memory device 100 may carve the data signal based on the 1-UI pulse and may then output the carved data signal. The 1-UI pulse may be generated based on internal read division clock signals which are delayed based on the control code determined in operation S100.

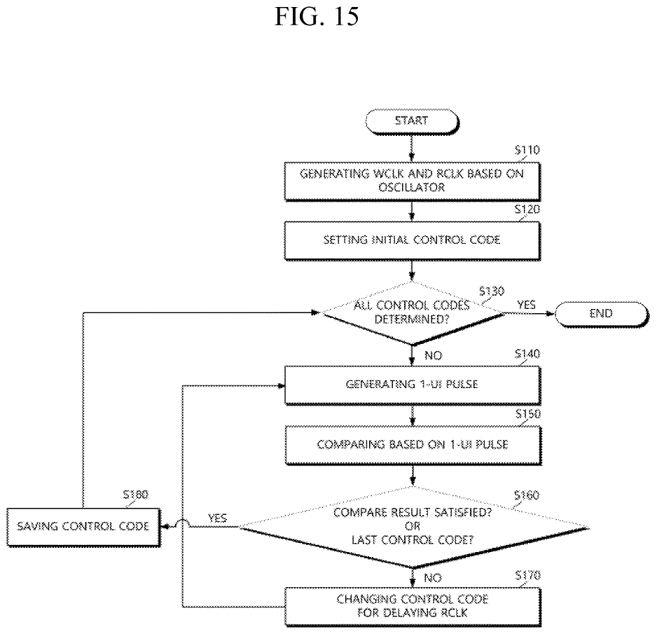

FIG. 15 is a flowchart describing an operating method of a skew compensating circuit according to an embodiment of the present disclosure. The operation of FIG. 15 may be performed for the skew compensating circuit 130 of FIG. 5 to determine a control signal. The operation of FIG. 15 may be performed in operation S100 of FIG. 14. An operation in which the skew compensating circuit 130 determines a control signal will be described with reference to FIGS. 5, 7, and 15.

In an embodiment, the operation of FIG. 15 may be simultaneously performed in parallel in the output circuits of FIGS. 1 and 2. For example, the control codes which are used in the output circuits connected to the data pins and the data strobe pin of FIGS. 1 and 2 may be determined in parallel. Accordingly, the memory device 100 may determine the control codes for compensating for the skews of the data pins and the data strobe pin within a short time, during the initialization sequence.

In operation S110, the oscillator may internally generate the data clock signal WCK, and the clock generating circuit 357 of FIG. 3 may generate the internal clock signals RCLK and WCLK based on the data clock signal WCK which the oscillator generates.

In an embodiment, the clock generating circuit 357 may output internal read division clock signals having different phases as internal read clock signals and may output internal write division clock signals having different phases as internal write clock signals.

In operation S120, the skew compensating circuit 130 sets an initial control code. For example, when the number of internal read division clock signals is 4, the skew compensating circuit 130 may set internal values of control codes respectively corresponding to delay circuits receiving four internal read division clock signals.

The initial values of the control codes may be variously set depending on the number and size of transistors which are controlled by the control bits of FIGS. 9B and 10B, and a method of setting initial values is not particularly limited thereto. For example, when the number of transistors to be controlled by control bits is 3, an initial control code for a control circuit which receives the first internal read division clock signal may be set to “100”, and initial control codes for control circuits which receive the remaining internal read division clock signals may be set to “000”.

In operation S130 to operation S180, the skew compensating circuit 130 may determine control codes based on 1-UI pulses generated by the internal read division clock signals, respectively.

For example, the skew compensating circuit 130 may determine control codes for the second internal read division clock signal RCLK<1> by using the first 1-UI pulse BL0_PS which is based on the first internal read division clock signal RCLK<0> and the second internal read division clock signal RCLK<1>. Likewise, as in the above description, the skew compensating circuit 130 may determine a control code for the third internal read division clock signal RCLK<2> by using the second 1-UI pulse BL1_PS and may determine a control code for the fourth internal read division clock signal RCLK<3> by using the third 1-UI pulse BL2_PS.

In operation S130, the skew compensating circuit 130 may check whether all the control codes are determined; when there is a control code which is not determined, operation S140 to operation S180 are repeated.

In operation S140, the pulse generating circuit 113_2 of FIG. 7 generates a 1-UI pulse signal based on the internal read division clock signals. For example, to determine the control code for the second internal read division clock signal RCLK<1>, the pulse generating circuit 113_2 may generate the first 1-UI pulse BL0_PS which is based on the first internal read division clock signal RCLK<0> and the second internal read division clock signal RCLK<1>.

In operation S150, the sampler 115 of FIG. 5 may compare the first reference voltage VREF1 with the magnitude of the DC signal obtained by performing low pass filtering on the output signal of the output circuit 113. The output signal of the output circuit 113 is a signal output based on the 1-UI pulse signal.

When it is determined in operation S160 that the magnitude of the DC signal obtained by performing low pass filtering on the output signal of the output circuit 113 is identical to the first reference voltage VREF1, in operation S180, the skew compensating circuit 130 of FIG. 5 may store a current control code. When the magnitude of the DC signal is determined to be different from the first reference voltage VREF1, in operation S170, a value of the control code is changed; afterwards, operation S140 is again performed. In operation S160, the skew compensating circuit 130 may determine whether the control code reaches the maximum value; when the control code reaches the maximum value, the skew compensating circuit 130 may store the control code. For example, as operation S170 is repeated, it may be possible to cope with an exceptional situation where the control code reaches the maximum value in a state where the magnitude of the DC signal obtained by performing low pass filtering on the output signal of the output circuit 113 is different from the first reference voltage VREF1.

Through the iteration of operation S130 to operation S180, the control code for delaying the second internal read division clock signal RCLK<1>, the control code for delaying the third internal read division clock signal RCLK<2>, and the control code for delaying the fourth internal read division clock signal RCLK<3> may be sequentially determined based on the first internal read division clock signal RCLK<0>.

According to embodiments of the present disclosure, the reliability of a semiconductor memory device may be improved.

According to embodiments of the present disclosure, a skew of the data signal DQ and the data strobe signal DQS output from the semiconductor memory device may be removed.

While the present disclosure has been described with reference to embodiments thereof, it will be apparent to those of ordinary skill in the art that various changes and modifications may be made thereto without departing from the spirit and scope of the present disclosure as set forth in the following claims.

What is claimed is:

1. A semiconductor memory device comprising:
a memory cell array including a memory cell storing data;
a plurality of data pins configured to transmit and receive the data;
a plurality of output circuits respectively connected to the plurality of data pins, wherein the plurality of output circuits include delay circuits, respectively, and output the data through the plurality of data pins based on an internal read clock signal; and
a skew compensating circuit configured to transmit a first control signal controlling the delay circuit of each of the plurality of output circuits to each of the plurality of output circuits.

2. The semiconductor memory device of claim 1, wherein the first control signal includes a control code implemented with a plurality of control bits, and
wherein the skew compensating circuit transmits different control codes to at least two output circuits among the plurality of output circuits respectively connected to the plurality of data pins.

3. The semiconductor memory device of claim 1, wherein the internal read clock signal includes a plurality of internal division clock signals,
wherein each of the plurality of output circuits includes:
a plurality of division clock delay circuits configured to receive the plurality of internal division clock signals, to delay the plurality of internal division clock signals, respectively, and to output delayed division clock signals.

4. The semiconductor memory device of claim 3, wherein each of the plurality of output circuits further includes:
a pulse generating circuit configured to output a plurality of 1-UI (unit interval) pulses whose high levels do not overlap each other, based on the delayed division clock signals;
a multiplexer configured to serialize and output driving signals corresponding to the data based on the plurality of 1-UI pulses; and
a driving circuit configured to output a data signal corresponding to the driving signals.

5. The semiconductor memory device of claim 1, further comprising:
a data strobe pin configured to transmit a data strobe; and
another output circuit including another delay circuit, connected to the data strobe pin, and configured to output the data strobe through the data strobe pin, based on the internal read clock signal.

6. The semiconductor memory device of claim 1, further comprising:
a sampler circuit connected to each of the plurality of data pins through a resistor and a first node;
a capacitor; and
a first switch configured to connect the first node and the capacitor, wherein the capacitor is connected to the first node through the first switch and is connected to a ground electrode; and
a second switch configured to connect the capacitor and a supply voltage electrode.

7. The semiconductor memory device of claim 6, wherein the sampler circuit configured to sample the data received through the data pins based on an internal write clock signal.

8. The semiconductor memory device of claim 6, wherein the first switch and the second switch are configured to be controlled based on a second control signal, and
wherein, during an initialization sequence of the semiconductor memory device, the first switch is configured to be turned on by the second control signal, and the second switch is configured to be turned off by the second control signal.

9. The semiconductor memory device of claim 6, wherein the first control signal includes a control code implemented with a plurality of control bits, and
wherein, during an initialization sequence of the semiconductor memory device, the skew compensating circuit is configured to determine control codes respectively corresponding to the plurality of data pins.

10. The semiconductor memory device of claim 9, further comprising:
an oscillator configured to generate a self-data clock signal;
a clock generating circuit configured to generate the internal read clock signal based on the self-data clock signal; and
a pattern generating circuit configured to generate a pattern signal maintaining a high level.

11. The semiconductor memory device of claim 10, wherein, in the initialization sequence,
the first switch is configured to be turned on,
the second switch is configured to be turned off, and
each of the plurality of output circuits is configured to transmit an output signal corresponding to the pattern signal to the sampler circuit through the resistor and the first node, based on the internal read clock signal generated based on the self-data clock signal.

12. The semiconductor memory device of claim 11, wherein the skew compensating circuit is configured to determine the control code, based on a result of comparing the output signal and a reference voltage.

13. The semiconductor memory device of claim 1, wherein the first control signal includes a control code implemented with a plurality of control bits,
wherein the delay circuit includes a plurality of delay elements, and
wherein each of the plurality of delay elements is configured to receive at least one control bit among the plurality of control bits.

14. A semiconductor memory device comprising:
a memory cell array including a memory cell storing data;
a data pin configured to transmit and receive the data;
an output circuit including a delay circuit, connected to the data pin, and configured to output an output signal obtained by carving an input signal to have a 1-UI (unit interval) pulse width based on an internal read clock signal;
a sampler circuit connected to the data pin and the output circuit through a low pass filter; and
a skew compensating circuit configured to transmit a control signal controlling the delay circuit to the output circuit,
wherein the low pass filter includes a resistor and a capacitor, and
wherein the low pass filter is configured to perform low pass filtering during an initialization sequence of the semiconductor memory device and to operate as a resistance circuit after the initialization sequence.

15. An operating method of a semiconductor memory device, the method comprising:
determining, at the semiconductor memory device, control codes controlling delay elements respectively included in a plurality of output circuits respectively connected to a plurality of data pins, during at least one initialization sequence of the semiconductor memory device;
after the at least one initialization sequence, delaying, at the semiconductor memory device, an internal read clock signal based on the control codes; and
after the at least one initialization sequence, outputting, at the semiconductor memory device, data through the plurality of data pins based on a delayed internal read clock signal in response to a read command of a memory controller.

16. The method of claim 15, wherein the determining of the control codes includes:
generating a first output signal, which is obtained by carving an input signal maintaining a high level to have a 1-UI (unit interval) pulse width, based on the internal read clock signal;
comparing a second output signal obtained by performing low pass filtering on the first output signal, with a reference voltage; and
determining the control codes, based on a result of the comparing.

17. The method of claim 15, further comprising:
generating, at an oscillator, a data clock signal; and
generating the internal read clock signal based on the data clock signal.

18. The method of claim 15, wherein the determining of the control codes includes:
independently determining the control codes respectively corresponding to the plurality of data pins.

19. The method of claim 18, wherein the determining of the control codes includes:
determining the control codes respectively corresponding to the plurality of data pins in parallel.

20. The method of claim 15, wherein the outputting of the data includes:
outputting, at at least two output circuits among the plurality of output circuits respectively connected to the plurality of data pins, the data based on different control codes.
